(19) United States
(12) Patent Application Publication
(10) Pub. No.: US 2007/0252148 A1
(43) Pub. Date: Nov. 1, 2007

(54) Thin film transistor substrate and method for manufacturing same

(75) Inventor: Shuo-Ting Yan, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/796,778

(22) Filed: Apr. 30, 2007

(30) Foreign Application Priority Data
Apr. 28, 2006 (TW) 95115388

(51) Int. Cl. H01L 29/04

(52) U.S. Cl. 257/59

(57) ABSTRACT

An exemplary TFT substrate (300) includes a substrate (310), a silicon layer (320), a insulating layer (330, 340), and a metal layer (350), the metal layer, the insulating layer, the silicon layer being formed on the substrate in that order from top to bottom. The insulating layer comprises a first insulating layer (330) and a second insulating (340), the second insulating layer covering part of the first insulating layer.

### FIELD OF THE INVENTION

The present invention relates to thin film transistor (TFT) substrates used in liquid crystal displays (LCDs) and methods of fabricating these substrates, and particularly to a TFT substrate and a method for fabricating the substrate which efficiently lower the drain current.

### GENERAL BACKGROUND

A typical liquid crystal display (LCD) is capable of displaying a clear and sharp image through millions of pixels that make up the complete image. The liquid crystal display has thus been applied to various electronic equipments in which messages or pictures need to be displayed, such as mobile phones and notebook computers. A liquid crystal panel is a major component of the LCD, and generally includes a thin film transistor (TFT) array substrate, a color filter substrate opposite to the TFT substrate, and a liquid crystal layer sandwiched between the two substrates.

Referring to FIG. 17, part of a typical TFT substrate is shown. The TFT substrate 100 includes a substrate 110, a silicon film 120 formed on the substrate 110, an insulating layer 130 formed on the silicon film 120, and a gate metal layer 140 formed on the insulating layer 130. The insulating layer 130 is a gate insulating layer. A source electrode 121 and a drain electrode 122 are formed at two ends of the silicon film 120 by doping phosphor ion therein. The source and drain electrodes 121, 122 are respectively connected to an external circuit through guiding wires.

In operation, external voltage is applied to the gate metal layer 140, the source and the drain electrodes 121, 122. The voltage loaded on the gate metal layer 140 induces a channel 123 at the silicon film 120 between the source electrode 121 and the drain electrode 122, transmitting through the insulating layer 130. A current is produced at the channel 123 under the voltage difference between the source electrode 121 and the drain electrode 122.

As shown in FIG. 18, a flow chart of a method for manufacturing the TFT substrate 100 is shown. The method has following steps:

step S10, providing the substrate 100;

step S11, forming the silicon (Si) layer 120, the insulating layer 130, the gate metal layer 140 and a photo-resist layer;

step S12, exposing and developing the photo-resist layer;

step S13, etching the gate metal layer 140;

step S14, forming the source electrode 121 and the drain electrode 122; and

step S15, removing the photo-resist layer.

In step S12, a photo mask is provided for exposing and developing the photo-resist layer to form a photo-resist pattern. In step S13, the gate metal layer 140 is etched, thereby forming a gate metal layer pattern, which corresponds to the photo-resist pattern. In step S14, phosphor ion is doped at two ends of the silicon film 120 to respectively form the source electrode 121 and the drain electrode 122. In step S15, the residual photo-resist layer is then removed by an acetone solution.

However, the insulating layer 130 has a limited insulating characteristics, a drain current is easy to be produced between the gate metal layer 140 and the source/drain electrodes 121, 122, when a corresponding thin film transistor (TFT) is turned off. The drain current influences the precision of the signals, especially the corresponding TFT is turned off. Thus, the reliability of the TFT substrate 100 is decreased and a good image quality can not be attained.

What is needed, therefore, is a method for fabricating a TFT substrate that can overcome the above-described problems. What is also needed is a TFT substrate fabricated by the above method.

### SUMMARY

An exemplary TFT substrate includes a substrate, a silicon layer, a insulating layer, and a metal layer, the metal layer, the insulating layer, the silicon layer being formed on the substrate in that order from top to bottom. The insulating layer comprises a first insulating layer and a second insulating, the second insulating layer covering part of the first insulating layer.

In one preferred embodiment, a method for fabricating a thin film transistor (TFT) substrate includes steps of: providing an insulating substrate; sequentially forming a silicon layer, a first insulating layer, a first metal layer and a first photo-resist layer on the insulating substrate; exposing and developing the first photo-resist layer to form a first photo-resist pattern; etching the first metal layer to form a first metal pattern corresponding to the photo-resist pattern; and depositing a second insulating layer on a part of the first photo-resist layer uncovered by the photo-resist pattern.

In an alternate preferred embodiment, a method for fabricating a thin film transistor (TFT) substrate includes steps of: providing an insulating substrate; sequentially forming a silicon layer, a first insulating layer, and a first photo-resist layer on the insulating substrate; exposing and developing the first photo-resist layer to form a first photo-resist pattern; depositing a second insulating layer on a part of the first photo-resist layer uncovered by the photo-resist pattern; removing the first photo-resist pattern; forming a gate metal layer and a second photo-resist layer on the second insulating layer and a part of the first insulating layer uncovered by the second insulating layer; exposing and developing the second photo-resist layer, thereby forming a second photo-resist pattern; etching the gate metal layer, thereby forming a gate metal pattern corresponding to the second photo-resist pattern; and removing the second photo-resist pattern.

Other advantages and novel features will become more apparent from the following detailed description when taken in conjunction with the accompanying drawings.

### BRIEF DESCRIPTION OF THE DRAWINGS

FIG. 1 is a schematic, top view of a pixel of a TFT substrate according to a first exemplary embodiment of the present invention.

FIG. 2 is a flowchart summarizing an exemplary method for fabricating the TFT substrate of FIG. 1.

FIGS. 3 to 8 are schematic, side cross-sectional views relating to main steps of fabricating the TFT substrate according to the method of FIG. 2.

FIG. 9 is a schematic, top view of a pixel of a TFT substrate according to a second exemplary embodiment of the present invention.

FIG. 10 is a flowchart summarizing an exemplary method for fabricating the TFT substrate of FIG. 9.

FIGS. 11 to 16 are schematic, side cross-sectional views relating to main steps of fabricating the TFT substrate according to the method of FIG. 10.

FIG. 17 is a schematic, top view of a pixel of a conventional TFT substrate. and

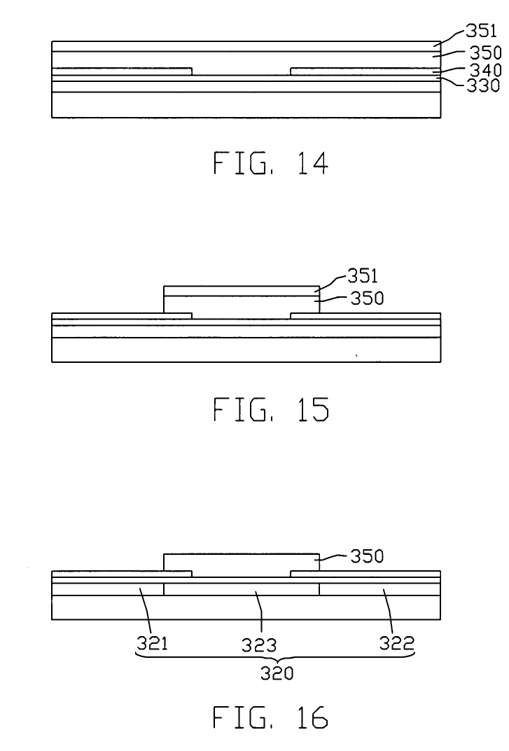

FIG. 18 is a flowchart summarizing a method for fabricating the TFT substrate of FIG. 17.

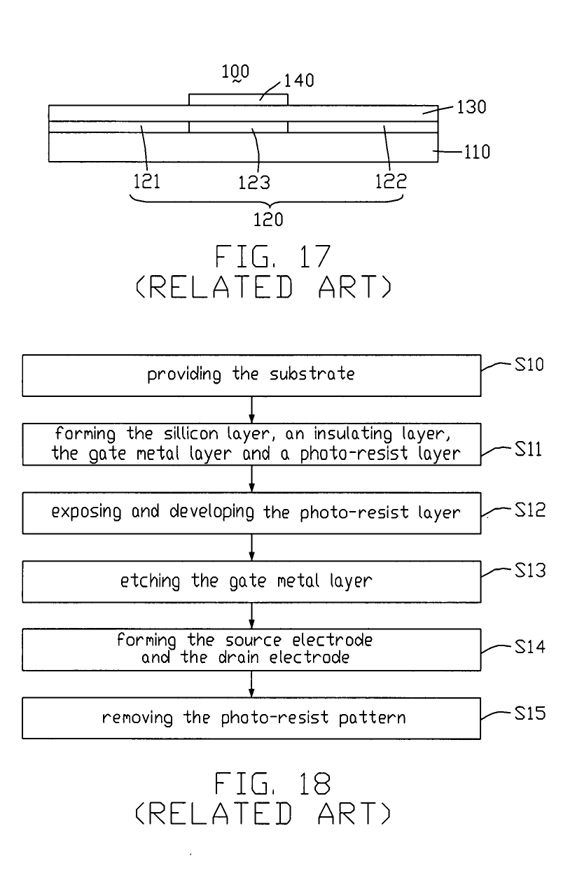

### DETAILED DESCRIPTION OF PREFERRED EMBODIMENTS

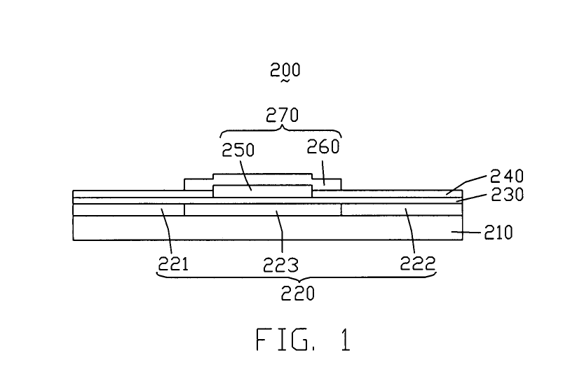

Referring to FIG. 1, part of a thin film transistor (TFT) substrate according to an exemplary embodiment of the present invention is shown. The TFT substrate 2 includes a substrate 210, a silicon layer 220, a first insulating layer 230, a second insulating layer 240, a first metal layer 250, and a second metal layer 260. The first insulating layer 230, the silicon layer 220 are formed on the substrate 210 in that order from top to bottom. The second insulating layer 240 covers a part of the first insulating layer 230, an opening (not labeled) therein is defined. The first metal layer 250 is embedded in the opening of the second insulating layer 240, and the second metal layer 260 is disposed on the first metal layer 250 and a part of the second insulating layer 240. The first metal layer 250 and the second metal layer 260 ohmic contact to define a gate electrode 270. A source electrode 221 and a drain electrode 222 are formed at two ends of the silicon film 220 by implanting phosphor ion therein. A channel region 223 is defined at the silicon film 220 between the source electrode 221 and the drain electrode 222, which has a channel length same to that of the second metal layer 260. The gate electrode 270, the source and drain electrodes 221, 222 are respectively connected to external circuits (not shown) through guiding wires.

In operation, voltages are respectively applied to the gate electrode 270, the source electrode 221, the drain electrode 222 by the external circuits. A channel is coupled under a gate voltage from the gate electrode 270 transmitting through the first insulating layer 230. Thus, a current is produced at the channel region 223 for the voltage difference between the source and the drain electrodes 221, 222.

Because the TFT substrate 200 has two insulating layers 230, 240, the second insulating layer 240 adds the thickness of the insulating layer between the gate electrode 270 and the source/drain electrodes 221, 222 adjacent to the channel region 223. Thus, the resistivity therebetween is added, which can decrease the coupling electrical field between the gate electrode 270 and the source/drain electrodes 221, 222. Therefore, for a predetermined gate voltage, drain voltage is lowered and the bad influence produced by the drain voltage is decreased. In addition, the electrical field between the source electrode 221 and the drain electrode 222 is also decreased because the thickness of the insulating layer adjacent to the source electrode 221 and the drain electrode 222 is increased. Thus, impact ionization effect adjacent to the drain electrode 222 is decreased and the possibility of producing the floating body effect is lowered. Thus, the reliability of the TFT substrate 20 is improved.

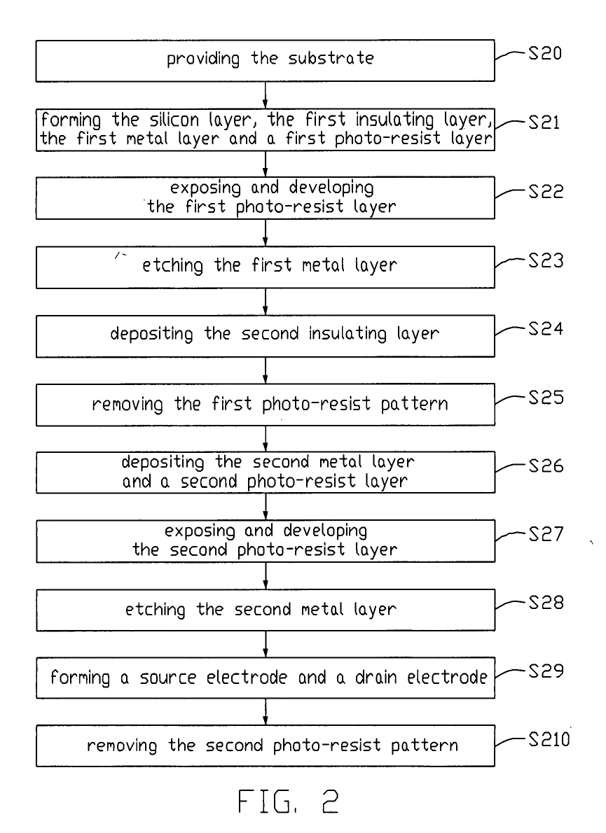

FIG. 2 is a flow chart of a method for manufacturing the TFT substrate 200. The method has following processes:

step S20, providing the substrate 210, the substrate being made from a transparent glass or quartz;

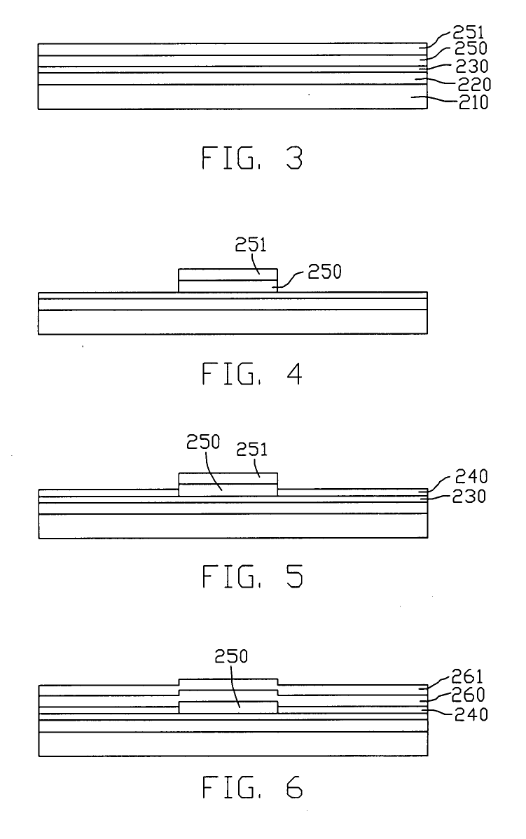

step S21 (as shown in FIG. 3), forming the silicon layer 220, the first insulating layer 230, the first metal layer 250 and a first photo-resist layer 251, the silicon layer 220, the first insulating layer 230, the first metal layer 250 being sequentially coated on the substrate 210 in that order from bottom to top, wherein the silicon layer 220 is amorphous silicon, the first insulating layer 230 is made from SiO₂, and the first metal layer is made from silver (Ag);

step S22, exposing and developing the first photo-resist layer, wherein a first photo mask having predetermined pattern is provided, the first photo-resist layer is exposed by a first photo-mask, and then is developed, thereby forming a first photo-resist pattern;

step S23, etching the first metal layer 250, thereby forming a first metal pattern corresponding to the first photo-resist pattern (as shown in FIG. 4);

step S24 (as shown in FIG. 5), depositing the second insulating layer 240, the second insulating layer 240 being deposited by a liquid phase deposition method, which is made from material of SiO₂ material doped with fluorine, having a thickness less than that of the first insulating layer 230;

step S25, removing the firs photo-resist layer;

step S26 (as shown in FIG. 6), depositing the second metal layer 260 and a second photo-resist layer 261, the second metal layer 260 and the second photo-resist layer 261 being deposited on the second insulating layer 240 and the first metal layer 250 in that order from bottom to top, wherein the second metal layer 260 also made from silver (Ag) ohmic contact with the first metal layer 250, having a same thickness to that of the first metal layer 250;

step S27, exposing and developing the second photo-resist layer, wherein a second photo mask having predetermined pattern is provided, the second photo-resist layer 261 is exposed by a second photo-mask, and then is developed, thereby forming a second photo-resist pattern;

step S28, etching the second metal layer 260, thereby forming a second metal pattern corresponding to the second photo-resist pattern (as shown in FIG. 7), wherein the second metal layer 260 covers the first metal layer 250 and a part of the adjacent second insulating layer 240;

step S29 (as shown in FIG. 8), forming the source electrode 221 and the drain electrode 222, phosphor ion being implanted into two ends of the silicon layer 220 to form the source electrode 221 and the drain electrode 222, a channel region 223 being defined therebetween; and

step S210, removing the second photo-resist layer.

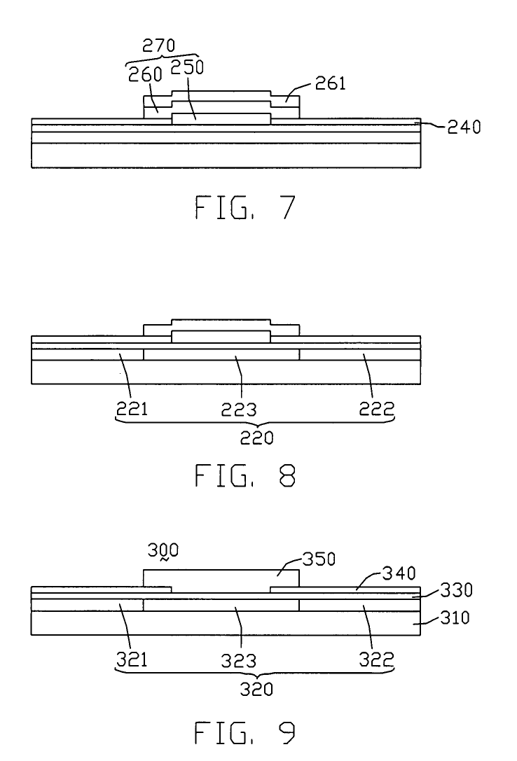

Referring to FIG. 9, part of a thin film transistor (TFT) substrate according to a second exemplary embodiment of the present invention is shown. The TFT substrate 300 includes a substrate 310, a silicon layer 320, a first insulating layer 330, a second insulating layer 340, and a gate metal layer 350. The second insulating layer 340, the first insulating layer 330, the silicon layer 320 are formed on the substrate 310 in that order from top to bottom. The second insulating layer 340 covers a part of the first insulating layer 330, an opening (not labeled) therein is defined. The gate metal layer 350 is disposed on a part of the first insulating layer 330 uncovered by the second insulating layer 340 and a part of the second insulating layer 340 adjacent to the opening. A source electrode 321 and a drain electrode 322 are formed at two ends of the silicon film 320 by implanting phosphor ion therein. A channel region 323 is defined at the silicon film 320 between the source electrode 321 and the drain electrode 322, which has a channel length same to that of the gate metal layer 350. The gate metal layer 350, the source and drain electrodes 321, 322 are respectively connected to an external circuits (not shown) through guiding wires.

In operation, voltages are respectively applied to the gate metal layer 350, the source electrode 321, the drain electrode 322 by the external circuits. A channel is coupled under a gate voltage from the gate metal layer 350 transmitting through the first insulating layer 330. Thus, a current is produced at the channel region 323 for the voltage difference between the source and the drain electrodes 321, 322.

Because the TFT substrate 300 has two insulating layers 330, 340, the second insulating layer 340 adds the thickness of the insulating layer between the gate metal layer 350 and the source/drain electrodes 321, 322 adjacent to the channel region 323. Thus, the resistivity therebetween is added, which can decrease the coupling electrical field between the gate metal layer 350 and the source/drain electrodes 321, 322. Therefore, for a predetermined gate voltage, drain voltage is lowered and the bad influence produced by the drain voltage is decreased. In addition, the electrical field between the source electrode 321 and the drain electrode 322 is also decreased because the thickness of the insulating layer adjacent to the source electrode 321 and the drain electrode 322 is increased. Thus, impact ionization effect adjacent to the drain electrode 322 is decreased and the possibility of producing the floating body effect is lowered. Thus, the reliability of the TFT substrate 300 is improved.

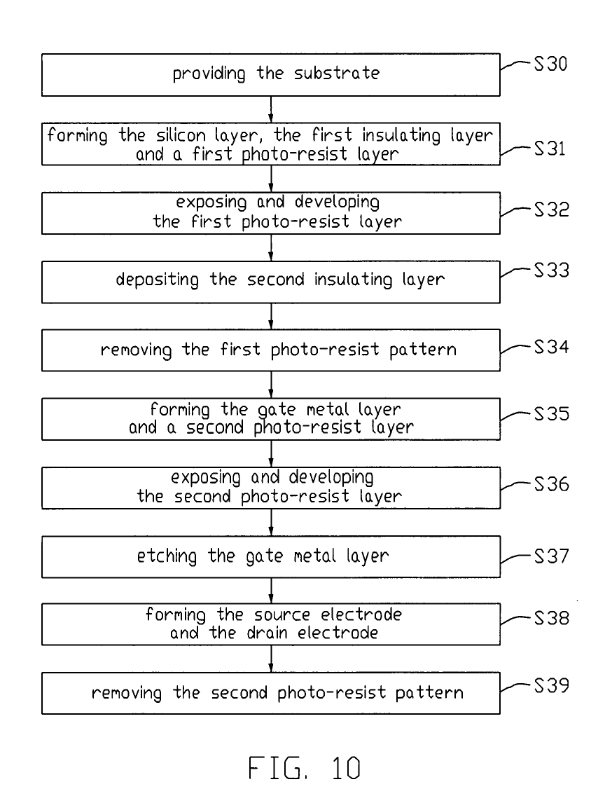

FIG. 10 is a flow chart of a method for manufacturing the TFT substrate 200. The method has following processes:

step S30, providing the substrate 310, the substrate being made from a transparent glass or quartz;

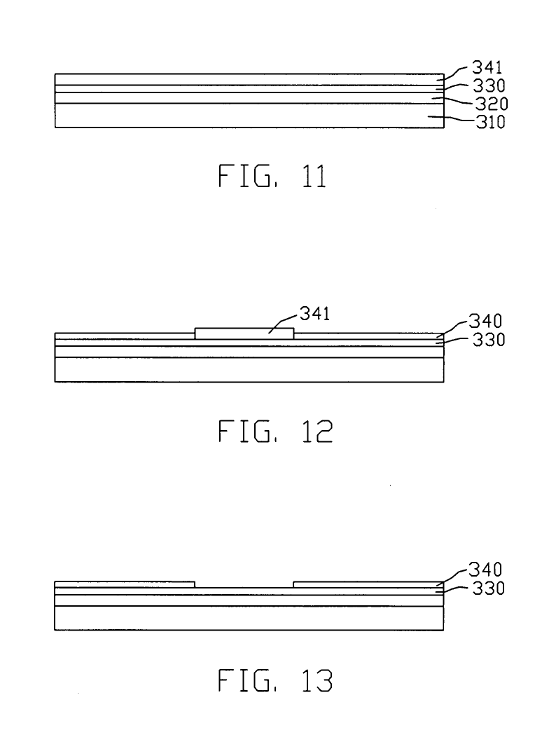

step S31 (as shown in FIG. 11), forming the silicon layer 320, the first insulating layer 330, and a first photo-resist layer 341, the silicon layer 320, the first insulating layer 330 and the first photo-resist layer 341 being sequentially coated on the substrate 310 in that order from bottom to top, wherein the silicon layer 320 is amorphous silicon, the first insulating layer 330 is made from SiO₂;

step S32, exposing and developing the first photo-resist layer 341, wherein a first photo mask having predetermined pattern is provided, the first photo-resist layer 341 is exposed by a first photo-mask, and then is developed, thereby forming a first photo-resist pattern;

step S33 (as shown in FIG. 12), depositing the second insulating layer 340, the second insulating layer 340 being deposited on the first insulating layer 330 uncovered by the first photo-resist pattern;

step S34 (as shown in FIG. 13), removing the first photo-resist pattern, thereby the opening in the second insulating layer 340 is formed;

step S35 (as shown in FIG. 14), forming the gate metal layer 350 and a second photo-resist layer 351, the gate metal layer 350 and the second photo-resist layer 351 being deposited on the second insulating layer 340 and a part of the first insulating layer 330 uncovered by the second insulating layer 340 in that order from bottom to top, wherein the gate metal layer 350 is made from silver (Ag);

step S37, exposing and developing the second photo-resist layer 351, wherein a second photo mask having predetermined pattern is provided, the second photo-resist layer 351 is exposed by a second photo-mask, and then is developed, thereby forming a second photo-resist pattern;

step S38, etching the gate metal layer 350, thereby forming a gate metal pattern corresponding to the second photo-resist pattern (as shown in FIG. 15), wherein the gate metal layer 350 covers a part of the first insulating layer 330 uncovered by the second insulating layer 340 and a part of the adjacent second insulating layer 340;

step S39 (as shown in FIG. 16), forming the source electrode 321 and the drain electrode 322, phosphor ion being implanted into two ends of the silicon layer 320 to form the source electrode 321 and the drain electrode 322, a channel region 323 being defined therebetween; and

step S310, removing the second photo-resist pattern.

Because the TFT substrate 300 has two insulating layers 330, 340, the second insulating layer 340 adds the thickness of the insulating layer between the gate metal layer 350 and the source/drain electrodes 321, 322 adjacent to the channel region 323. Thus, the resistivity therebetween is added, which can decrease the coupling electrical field between the gate metal layer 350 and the source/drain electrodes 321, 322. Therefore, for a predetermined gate voltage, drain voltage is lowered and the bad influence produced by the drain voltage is decreased.

In alternate modifications, the substrate 210 also can be made from an opaque or translucent material. In addition, the substrate 210 may be flexible. The silicon layer 220 may not only be amorphous silicon but also poly-crystalline silicon. The first and the second metal layer 250, 260 may be made from material including any one or more items selected from the group consisting of aluminum (Al), molybdenum (Mo), copper (Cu), chromium (Cr), and tantalum (Ta). The second insulating layer 240 may also be silicon oxide or other organic insulating material.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A TFT substrate comprising:
a substrate, a silicon layer, a insulating layer, and a metal layer, the metal layer, the insulating layer, the silicon layer being formed on the substrate in that order from top to bottom,
wherein the insulating layer comprises a first insulating layer and a second insulating, the second insulating layer covering part of the first insulating layer.

2. The TFT substrate as claimed in claim 1, wherein an opening is formed in the second insulating layer, above the first insulating layer.

3. The TFT substrate as claimed in claim 2, wherein the metal layer is a gate metal layer.

4. The TFT substrate as claimed in claim 3, wherein the metal layer comprises a first metal layer and a second metal layer, and the first metal layer is embedded in the opening of the second insulating layer, and the second metal layer is disposed on the first metal layer and a part of the second insulating layer.

5. The TFT substrate as claimed in claim 4, wherein the first metal layer and the second metal layer ohmic contact.

6. The TFT substrate as claimed in claim 5, wherein a source electrode and a drain electrode are formed at two ends of the silicon film by implanting phosphor ion therein.

7. The TFT substrate as claimed in claim 6, wherein a channel region is defined at the silicon film between the source electrode and the drain electrode, which has a channel length same to that of the second metal layer.

8. The TFT substrate as claimed in claim 3, wherein the gate metal layer is disposed on a part of the first insulating layer uncovered by the second insulating layer and a part of the second insulating layer adjacent to the opening.

9. A method for fabricating a thin film transistor (TFT) substrate, the method comprising:
providing an insulating substrate;
sequentially forming a silicon layer, a first insulating layer, a first metal layer and a first photo-resist layer on the insulating substrate;
exposing and developing the first photo-resist layer to form a first photo-resist pattern;
etching the first metal layer to form a first metal pattern corresponding to the photo-resist pattern; and
depositing a second insulating layer on a part of the first photo-resist layer uncovered by the photo-resist pattern.

10. The method as claimed in claim 9, further comprising the steps of:
depositing a second metal layer and a second photo-resist layer on the second insulating layer and the first metal layer;
exposing and developing the second photo-resist layer to form a second photo-resist pattern;
etching the second metal layer, thereby forming a second metal pattern corresponding to the second photo-resist pattern; and
removing the second photo-resist pattern.

11. The method as claimed in claim 10, wherein the first insulating layer is a SiO₂.

12. The method as claimed in claim 10, wherein the second insulating layer is made from material of SiO₂ material doped with fluorine.

13. The method as claimed in claim 10, wherein the second insulating layer is made by a liquid phase deposition method.

14. The method as claimed in claim 10, wherein the first and the second metal layer is made from material including any one or more items selected from the group consisting of silver (Ag), aluminum (Al), molybdenum (Mo), copper (Cu), chromium (Cr), and tantalum (Ta).

15. The method as claimed in claim 10, wherein the silicon layer may be amorphous silicon or poly-crystalline silicon.

16. A method for fabricating a thin film transistor (TFT) substrate, the method comprising:
providing an insulating substrate;
sequentially forming a silicon layer, a first insulating layer, and a first photo-resist layer on the insulating substrate;
exposing and developing the first photo-resist layer to form a first photo-resist pattern;
depositing a second insulating layer on a part of the first photo-resist layer uncovered by the photo-resist pattern;
removing the first photo-resist pattern;
forming a gate metal layer and a second photo-resist layer on the second insulating layer and a part of the first insulating layer uncovered by the second insulating layer;
exposing and developing the second photo-resist layer, thereby forming a second photo-resist pattern;
etching the gate metal layer, thereby forming a gate metal pattern corresponding to the second photo-resist pattern; and
removing the second photo-resist pattern.

17. The method as claimed in claim 16, further comprising a step of implanting phosphor ion into two ends of the silicon layer to form the source electrode and the drain electrode, a channel region being defined therebetween.
